(19) United States
(12) Patent Application Publication
(10) Pub. No.: US 2026/0096372 A1
(43) Pub. Date: Apr. 2, 2026

(54) EXHAUSTED GAS CHANNEL PLATE

(71) Applicant: ASM IP Holding B.V., Almere (NL)

(72) Inventors: Leonard Rodriguez, Phoenix, AZ (US); Michael Schmotzer, Chandler, AZ (US)

(21) Appl. No.: 19/339,655

(22) Filed: Sep. 25, 2025

Related U.S. Application Data
(60) Provisional application No. 63/701,465, filed on Sep. 30, 2024.

(51) Int. Cl. H01L 21/67; B05B 1/00

(52) U.S. Cl. CPC H10P 72/0402; B05B 1/005

(57) ABSTRACT

A showerhead assembly is provided. The showerhead assembly includes a showerhead plate, a gas channel plate and a connection path between the showerhead plate and the gas channel plate. The gas channel plate includes a showerhead distribution plenum that is coupled to inner-through holes of the showerhead plate. The gas channel further includes an exhaust plenum that is coupled to outer-through holes of the showerhead plate. The connection path connects the showerhead distribution plenum to the exhaust plenum. Such a design allows purging a perimeter of the connection between the gas channel plate and the showerhead plate. The constant purge flow, thus, assists in significantly reducing uncontrolled diffusion from gas channel plate and/or showerhead plate to the wafer.

### CROSS-REFERENCE TO RELATED APPLICATIONS

This application is a nonprovisional of, and claims priority to and the benefit of, U.S. Provisional Patent Application No. 63/701,465, filed Sep. 30, 2024 and entitled “EXHAUSTED GAS CHANNEL PLATE,” which is hereby incorporated by reference herein.

### FIELD

The present disclosure relates generally to the field of semiconductor processing apparatus, associated processing methods, and to the field of device and integrated circuit manufacture. More particularly, the present disclosure generally relates to showerhead assemblies, semiconductor processing systems including such showerhead assemblies and associated methods of processing a substrate within a reaction chamber.

### BACKGROUND

Existing precursor distribution systems make use of showerheads to evenly distribute the precursor over the silicon wafer below. The showerhead is formed from two parts: a perforated plate for the actual showerhead and a backing plate to form the plenum behind the showerhead. Into this plenum, both the precursor and inert gases are delivered with the gases spreading across the showerhead while inside the plenum. However, the showerhead cannot have exit holes right at the joint between these parts, so there is a volume at the very edge that can generate stagnant flows. These stagnant flows trap precursors, allowing them to diffuse out of the showerhead after the bulk of the precursor has already been removed by the inert gas. It can then react in an uncontrolled manner, yielding non-desired non-ALD growth on the wafer.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to showerhead assemblies, semiconductor processing systems including showerhead assemblies, and methods for regulating gas flow to and from a reaction chamber when performing a process.

A showerhead assembly is provided. Shower head assembly includes a showerhead plate. The showerhead plate includes a plurality of inner through-holes extending through the showerhead plate from an upper plate surface to a lower plate surface, the plurality of inner through-holes positioned in an inner region of the showerhead plate. The plurality of outer through-holes is disposed in a concentric ring around the inner region and extends through the showerhead plate from the upper plate surface to the lower plate surface. A gas channel plate is also provided. The gas channel plate includes a showerhead distribution plenum coupled to the inner through-holes. The showerhead plate also includes an exhaust plenum coupled to the outer through-holes. The showerhead assembly further includes a connection path connecting the showerhead distribution plenum to the exhaust plenum.

A method of regulating gas flow to and from a reaction chamber when performing a process is provided. The method includes introducing a process gas into the reaction chamber. The method also includes allowing at least a portion of the process gas to flow to an exhaust plenum through a connection path prior to flowing the process gas through a showerhead plate of the reaction chamber on to a substrate. The connection path couples the exhaust plenum with a showerhead distribution plenum. The method finally includes purging the reaction chamber.

A semiconductor processing system is provided. The semiconductor processing system includes a reaction chamber. The system further includes a showerhead assembly configured to regulate gas flow to and from the reaction chamber. The showerhead assembly includes a showerhead plate. The showerhead plate includes a plurality of inner through-holes extending through the showerhead plate from an upper plate surface to a lower plate surface, the plurality of inner through-holes positioned in an inner region of the showerhead plate. The plurality of outer through-holes is disposed in a concentric ring around the inner region and extend through the showerhead plate from the upper plate surface to the lower plate surface. The system further includes a gas channel plate. The gas channel plate includes a showerhead distribution plenum coupled to the inner through-holes. The gas channel plate further includes an exhaust plenum coupled to the outer through-holes. Further, the showerhead assembly includes a connection path connecting the showerhead distribution plenum to the exhaust plenum. Finally, the showerhead assembly includes an exhaust channel coupled to the exhaust plenum, wherein the exhaust channel is configured to dispose gas flow external to the reaction chamber.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary semiconductor processing system configured to process a substrate in accordance with one or more embodiments of the disclosure.

FIG. 2A illustrates a cross-section view of a showerhead assembly included in a reactor of semiconductor processing system of FIG. 1 in accordance with one or more embodiments of the disclosure.

FIG. 2B illustrates a view of a portion of the showerhead assembly of FIG. 2A in accordance with one or more embodiments of the disclosure.

FIG. 2C illustrates a view of a conventional showerhead assembly to distinguish from the one or more embodiments of the disclosure.

FIG. 3 illustrates a flow diagram to regulate gas flow to and from a reaction chamber of semiconductor processing system of FIG. 1 when performing a process.

FIGS. 4A-4C illustrate various embodiments of a joining portion of a connection path included in the showerhead assembly, which is included in a reactor of semiconductor processing system of FIG. 1 in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly, to this, it will be understood the term “under,” “underlying,” or “below” will be construed to be relative concepts.

Various embodiments of the present disclosure relate to showerhead assemblies, semiconductor processing systems including such showerhead assemblies, and associated methods for processing substrates.

Commonly utilized showerhead assemblies can include a first series of through-holes (i.e., apertures) through which process gas is introduced into an associated reaction chamber (i.e., gas introduction through-holes) and a second series of through-holes through which excess process gas, inactive gas (e.g., purge gases, carrier gases), and any reaction by-products are exhausted from the reaction chamber (i.e., gas exhaust through-holes). The dimensions (e.g., the diameter) of such through-holes are normally fixed and are determined by the mechanical processes employed in fabricating the through-holes. However, having fixed dimensioned through-holes can detrimentally effect substrate processing when utilizing certain processing methods.

As a non-limiting example, atomic layer deposition (ALD) processes commonly comprise a two step process where (a) process gas (e.g., precursors/reactants and the like) is introduced into the reaction chamber through the showerhead assembly (commonly referred as the pulsing step) and (b) excess process gas and any reaction by-products are exhausted from the reaction chamber through the showerhead assembly (commonly referred to as the purging step). In certain examples, during the pulsing step the process gas resides within a reaction space within the reaction chamber for an adequate time period to allow saturation of the surface of the substrate and/or completion of reactions with an absorbed species on the substrate. During the purging step the excess process gas and any reaction byproducts are normally removed as rapidly as possible so that the cycle time of the ALD process and hence the throughput and/or deposition rate is optimized.

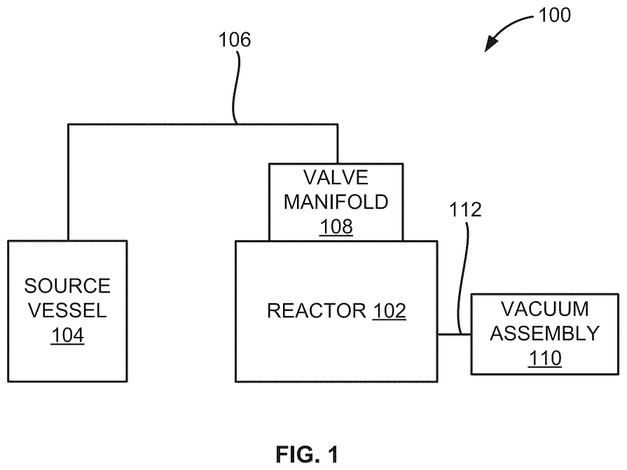

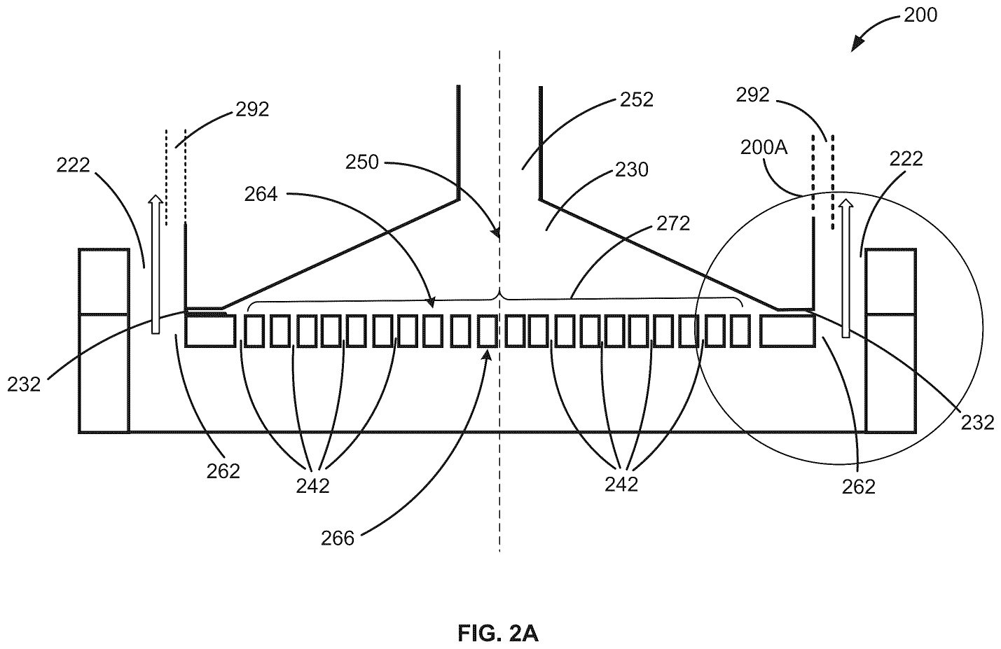

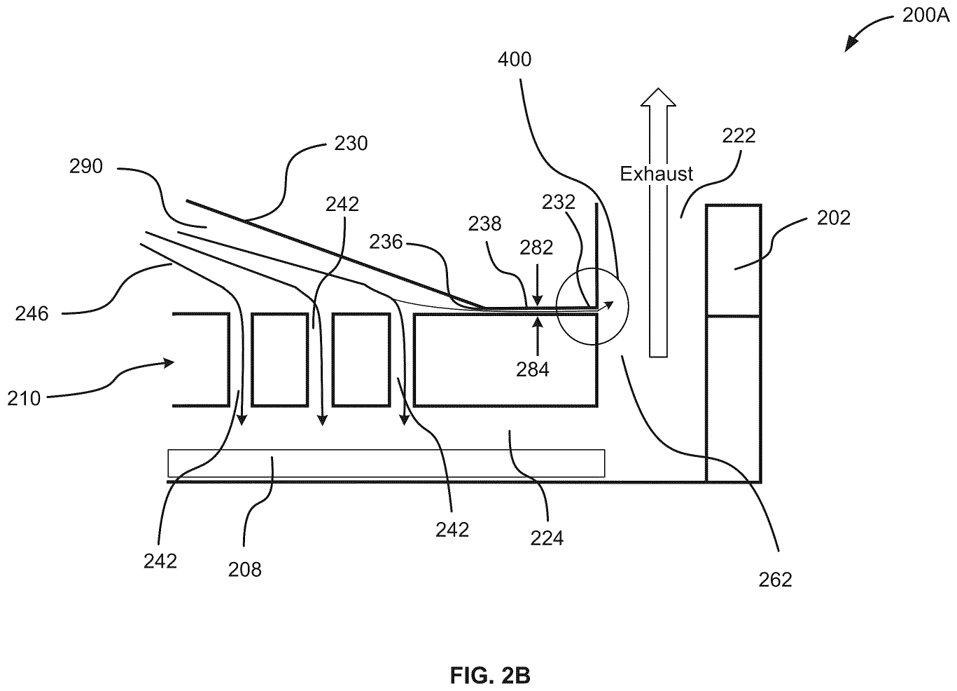

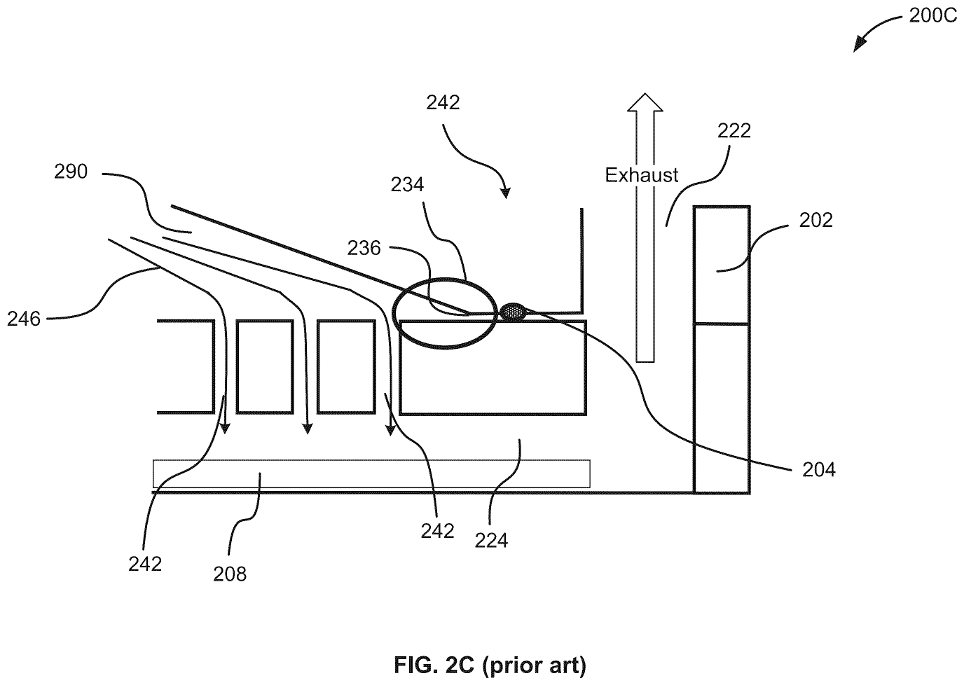

Turning now to the figures, FIG. 1 illustrates an exemplary semiconductor processing system 100 including a reactor 102 configured to process a substrate (e.g., the substrate 208 of FIG. 2). The reactor 102 may be configured to deposit a layer on a substrate, perform etching, and the like. The semiconductor processing system 100 may further comprise a source vessel 104 configured to contain or hold a chemistry (e.g., a precursor/reactant, an inactive gas, and the like) used in a semiconductor manufacturing process. The chemistry in the source vessel 104 may be in a solid, liquid, or gas phase initially. In the case of a solid or a liquid chemistry, the solid or liquid may be converted to a gas phase. For example, the source vessel 104 may comprise various devices and/or systems to convert a solid or a liquid to a gas. The conversion to a gas phase may occur within the source vessel 104. In addition, the semiconductor processing system 100 may further comprise a gas line 106 to transport the gas to the reactor 102. For example, the gas line 106 may be coupled to the source vessel 104 at a first end and the reactor 102 at a second end. In various embodiments, the semiconductor processing system 100 may further comprise a valve manifold 108 configured to provide controlled flow and mixing of multiple gases prior to entry into the reactor 102. The valve manifold 108 may be coupled directly to the reactor 102 and may be coupled to the gas line 106 and configured to receive the gas from the source vessel 104. In addition, the semiconductor processing system 100 may include a vacuum assembly 110 in fluid communication with the reactor 102 by a vacuum line 112. The vacuum assembly 110 (and associated vacuum line 112) can be employed to remove excess chemistry and reaction by-products from reactor 102 as well as controlling the pressure within the reactor 102.

FIG. 2A illustrates a cross-section of a showerhead assembly 200 included in reactor 102 of FIG. 1. FIG. 2B further illustrates an exploded view 200A of a portion of showerhead assembly 200. As shown in FIGS. 2A and 2B, showerhead assembly 200 includes a showerhead plate 210. Showerhead plate 210 includes a plurality of inner through-holes 242 and a plurality of outer through holes 262. As shown in FIG. 2A, showerhead assembly 200 is generally concentric to central axis 250. That is, the cross-section of showerhead assembly 200 shown in FIG. 2A is symmetric on either side of central axis 250.

In exemplary embodiments, plurality of inner through-holes 242 extend through the showerhead plate 210 from an upper plate surface 264 to lower plate surface 266. In such examples, the plurality of inner through-holes 242 may be positioned in an inner region 272 of showerhead plate 212, the inner region 272 being concentric to the central axis 250. As a non-limiting example, the plurality of inner through holes 242 of the showerhead plate 210 can be employed for introducing process gas into the reaction chamber (i.e., the plurality of inner through holes 242 comprise gas introduction through-holes).

In exemplary embodiments, plurality of outer through-holes 262 are disposed in a concentric ring around the inner region 272 and extend through the showerhead plate 210 from the upper plate surface 264 to lower plate surface 266. In such examples, plurality of outer through-holes 262 may be positioned at a first radial distance from the central axis 250. As a non-limiting example, the plurality of outer through-holes 262 of the showerhead plate 210 can be employed for exhausting process gas (and any reaction byproducts) from reaction chamber (i.e., the plurality of outer through-holes 262 comprise/couple with gas exhaust through-holes).

As shown in FIGS. 2A and 2B, showerhead assembly 200 includes a gas channel plate (GCP) 230. GCP 230 includes a main inlet 252 configured to fluidically couple with a gas source via a valve manifold. GCP 230 is designed to distribute a gas 246 (e.g., from the gas source) evenly through showerhead plate 210 to a reaction space 224 (e.g., within the reaction chamber). Accordingly, in some exemplary embodiments, showerhead plate 210 is disposed beneath GCP 230.

GCP 230 further includes a showerhead distribution plenum 290 that is fluidically coupled to main inlet 252. Showerhead distribution plenum 290 is further coupled to inner through-holes 242 of showerhead plate 210. GCP 230 also includes an exhaust plenum 222 that is coupled to outer through-holes 262. The exhaust plenum 222 can be at least partially defined by an outer GCP wall 202. Any process gas that is to be exhausted is removed by flowing through outer through-holes 262 and exhaust plenum 222. Exhaust plenum 222 may then flow process gas external to reactor 102. In exemplary embodiments, showerhead assembly 200 may further include or be coupled to exhaust channel 292, which is coupled to exhaust plenum 222. Accordingly, the exhaust channel is configured to receive gas flow from the exhaust plenum 222 and dispose it external to the reactor 102.

Referring now to FIG. 2C illustrating an exploded view of a conventional showerhead assembly 200C. As shown in FIG. 2C, GCP 230 is coupled to showerhead plate 210 and form two plenums: an inner plenum for precursor distribution and an outer plenum for exhaust collection. In conventional assemblies, these plenums are separated by a wall with an O-ring 204 providing a gas-tight seal. In some conventional examples, the thickness of O-ring 204 creates a small annulus, bounded by showerhead plate 210, GCP 230 and the O-ring 204. Region 234 includes the joint between the two plenums and the volume in region 234 generates stagnant flows.

Referring now back to FIG. 2B, showerhead assembly 200 further includes a connection path 238 that couples showerhead distribution plenum 290 with the exhaust plenum 222. As shown in FIG. 2B, O-ring 204 (illustrated in FIG. 2C) is eliminated and replaced with connection path 238 having a desired height h. Connection path 238 allows a constant flow of gases. Accordingly, at least a percentage of the gases introduced through main inlet 252 flows into a connection inlet 236, through connection path 238 and out of a connection outlet 232 into exhaust plenum 222.

In exemplary embodiments, connection path 238 is designed to have a desired height h that allows an acceptable percentage of total flow to the exhaust plenum 222 via connection path 238. In exemplary embodiments, this acceptable percentage is within five to fifteen percent of total flow to the exhaust plenum 222. In exemplary embodiments, connection path 238 is designed to have a height h that allows ten percent of the total flow from showerhead distribution plenum 290 through to exhaust plenum 222 via connection path 238.

The height h of the connecting path 238 is the distance between the bottom surface 282 of GCP 230 adjacent to the exhaust plenum and the top surface 284 of showerhead plate 210 adjacent to the outer through holes 262 is height h. In exemplary embodiments height h is greater than 0.2 millimeter. In further exemplary embodiments, height h is 0.6 mm. Accordingly, connection path 238 (having a height h) allows constant purge flow and significantly reduces uncontrolled diffusion from showerhead plate to the wafer during purging.

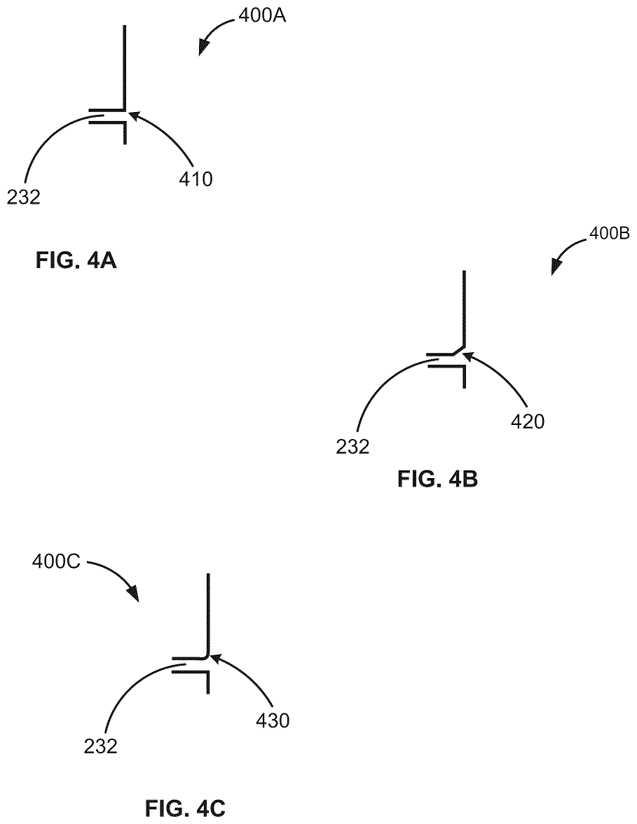

In exemplary embodiments, connection path 238 further includes a joining portion 400 at which connection path 238 and exhaust plenum 222 are coupled. FIGS. 4A, 4B and 4C illustrate various embodiments of joining portion 400. As shown in FIG. 4A, in exemplary embodiments, joining portion 400A may comprise a square-shaped joining portion 410. As shown in FIG. 4B, in exemplary embodiments, joining portion 400B may comprise a chamfered-shaped joining portion 420. As shown in FIG. 4C, in exemplary embodiments, joining portion 400C may comprise a rounded joining portion 430. Thus, in exemplary embodiments, shape of joining portion 400 may vary to accommodate and/or control the height h of the connection path and/or percentage of total flow of process gas from showerhead plenum to the exhaust plenum via connection path 238.

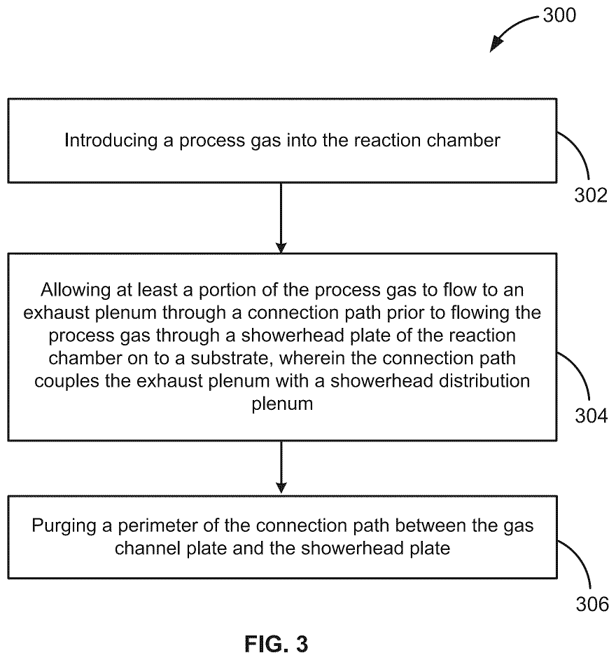

FIG. 3 illustrates a method 300 of regulating gas flow to and from a reaction chamber, such as reactor 102, when performing a process. Method 300 includes introducing a process gas into the reaction chamber, as shown with box 302.

Method 300 further includes allowing at least a portion of the process gas to flow to an exhaust plenum, such as exhaust plenum 222, through a connection path, such as connection path 238, prior to flowing the process gas through a showerhead plate, such as showerhead plate 210, of the reaction chamber on to a substrate, such as substrate 208, wherein the connection path couples the exhaust plenum with a showerhead distribution plenum, as shown with box 304. Exemplary embodiments of method 300 further include allowing within five to fifteen percent of process gas to flow to an exhaust plenum. Exemplary embodiments of method 300 further include allowing within five to fifteen percent of process gas to flow to an exhaust plenum comprises allowing ten percent of process gas to flow to an exhaust plenum. Exemplary embodiments of method 300 include flowing the process gas from the exhaust plenum to an exhaust channel to further dispose it external to the reaction chamber.

Method 300 further includes purging the reaction chamber, as shown with box 306. In exemplary embodiments of method 300 height of the connection path is greater than 0.2 millimeter. In further exemplary embodiments of method 300, the height of the connection path is 0.6 millimeter. In exemplary embodiments, method 300 includes radially aligning a plurality of outer-through holes of a showerhead plate of the reaction chamber with the exhaust plenum.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A showerhead assembly comprising:
a showerhead plate comprising:
a plurality of inner through-holes extending through the showerhead plate from an upper plate surface to a lower plate surface, the plurality of inner through-holes positioned in an inner region of the showerhead plate; and
a plurality of outer through-holes disposed in a concentric ring around the inner region and extending through the showerhead plate from the upper plate surface to the lower plate surface; and
a gas channel plate comprising:
a showerhead distribution plenum coupled to the plurality of inner through-holes; and
an exhaust plenum coupled to the plurality of outer through-holes; and
a connection path connecting the showerhead distribution plenum to the exhaust plenum.

2. The showerhead assembly of claim 1, wherein height of the connection path is greater than 0.2 millimeter.

3. The showerhead assembly of claim 2, wherein the height of the connection path is 0.6 millimeter.

4. The showerhead assembly of claim 1, wherein the exhaust plenum is coupled to an exhaust channel to dispose process gas from the exhaust plenum external to a reaction chamber comprising the showerhead assembly.

5. The showerhead assembly of claim 1, wherein the connection path is configured to allow within five percent to fifteen percent of total flow to the exhaust plenum, prior to flowing through the showerhead plate.

6. The showerhead assembly of claim 5, wherein the connection path is configured to allow ten percent of the total flow to the exhaust plenum.

7. The showerhead assembly of claim 1, wherein the connection path comprises a joining portion, wherein the joining portion is configured to couple the connection path to the exhaust plenum, and wherein shape of the joining portion is at least one of: rounded, chamfered, or square.

8. A method of regulating gas flow to and from a reaction chamber when performing a process, the method comprising:
introducing a process gas via a gas connection plate into the reaction chamber and distributed therethrough by a showerhead plate, the showerhead plate including an exhaust plenum and a showerhead distribution plenum;
allowing at least a portion of the process gas to flow to the exhaust plenum through a connection path, wherein the connection path is configured to couple the exhaust plenum with the showerhead distribution plenum; and
purging a perimeter of the connection path between the gas channel plate and the showerhead plate.

9. The method of claim 8, wherein height of the connection path is greater than 0.2 millimeter.

10. The method of claim 9, wherein the height of the connection path is 0.6 millimeter.

11. The method of claim 8, wherein allowing at least the portion of the process gas to flow to the exhaust plenum through the connection path further comprises allowing within five to fifteen percent of process gas to flow to an exhaust plenum.

12. The method of claim 11, wherein allowing within five to fifteen percent of process gas to flow to an exhaust plenum comprises allowing ten percent of process gas to flow to an exhaust plenum.

13. The method of claim 8, wherein allowing at least the portion of the process gas to flow through the exhaust plenum further comprises flowing the process gas from the exhaust plenum to the exhaust channel to further dispose it external to the reaction chamber.

14. The method of claim 8, wherein the connection path comprises a joining portion wherein the joining portion is configured to couple the connection path to the exhaust plenum, and wherein shape of the joining portion is at least one of: rounded, chamfered, or square.

15. A semiconductor processing system comprising:
a reaction chamber;
a showerhead assembly configured to regulate gas flow to and from the reaction chamber, the showerhead assembly comprising:
a showerhead plate comprising:
a plurality of inner through-holes extending through the showerhead plate from an upper plate surface to a lower plate surface, the plurality of inner through-holes positioned in an inner region of the showerhead plate; and
a plurality of outer through-holes disposed in a concentric ring around the inner region and extending through the showerhead plate from the upper plate surface to the lower plate surface; and
a gas channel plate comprising:
a showerhead distribution plenum coupled to the plurality of inner through-holes; and
an exhaust plenum coupled to the plurality of outer through-holes; and
a connection path connecting the showerhead distribution plenum to the exhaust plenum;
an exhaust channel coupled to the exhaust plenum, wherein the exhaust channel is configured to dispose gas flow external to the reaction chamber.

16. The semiconductor processing system of claim 15, wherein height of the connection path is 0.6 millimeter.

17. The semiconductor processing system of claim 15, wherein the plurality of outer-through holes and the exhaust plenum are radially aligned with each other.

18. The semiconductor processing system of claim 15, wherein the connection path is configured to allow ten percent of total gas flow to the exhaust plenum.

19. The semiconductor processing system of claim 15, further comprising:
a valve manifold constructed and arranged to control a supply of gas to the showerhead assembly from a gas source.

20. The semiconductor processing system of claim 19, further comprising:
a vacuum assembly coupled to the exhaust channel and constructed and arranged for exhausting gas from the reaction chamber.
